(19) United States
(12) Patent Application Publication
(10) Pub. No.: US 2025/0126799 A1
(43) Pub. Date: Apr. 17, 2025

(54) SEMICONDUCTOR DEVICE

(71) Applicant: Samsung Electronics Co., Ltd., Suwon-si (KR)

(72) Inventors: Kang-Oh YUN, Suwon-si (KR); Yunjo LEE, Suwon-si (KR); Dongjin LEE, Suwon-si (KR); Jaeduk LEE, Suwon-si (KR)

(73) Assignee: Samsung Electronics Co., Ltd., Suwon-si (KR)

(21) Appl. No.: 18/673,528

(22) Filed: May 24, 2024

(30) Foreign Application Priority Data
Oct. 11, 2023 (KR) 10-2023-0135201

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device may include a substrate containing first to third doping regions, first and second gate structures between the first and second doping regions, and a gate separation layer between the first and second gate structures. Each of the first and second gate structures may include a first gate dielectric layer, a first gate conductive layer on the first gate dielectric layer, and a second gate conductive layer between the gate separation layer and the first gate conductive layer. The gate separation layer may include a first sidewall in contact with the first gate structure and a second sidewall in contact with the second gate structure. A top surface of the gate separation layer may be at a same level as a top surface of the second gate conductive layer.

### CROSS-REFERENCE TO RELATED APPLICATION

This U.S. nonprovisional application claims priority under 35 U.S.C § 119 to Korean Patent Application No. 10-2023-0135201, filed on Oct. 11, 2023 in the Korean Intellectual Property Office, the disclosure of which is hereby incorporated by reference in its entirety.

### BACKGROUND

Inventive concepts relate to a semiconductor device, and more particularly, to a semiconductor device including a transistor.

Semiconductor devices have an important role in the electronic industry because of their small size, multi-functionality, and/or low fabrication cost. Semiconductor devices may encompass semiconductor memory devices storing logic data, semiconductor logic devices processing operations of logic data, and hybrid semiconductor devices having both memory and logic elements.

Recently, high speed and low consumption of electronic products require that semiconductor devices embedded in the electronic products should have high operating speed and/or lower operating voltage. However, an increase in integration of semiconductor devices may cause a reduction in electrical properties and production yield of semiconductor devices. Therefore, many studies have been conducted to increase electrical properties and production yield of semiconductor devices.

### SUMMARY

Some embodiments of inventive concepts provide a semiconductor device with increased reliability and improved electrical properties.

According to an embodiment of inventive concepts, a semiconductor device may include a substrate including a first doping region, a second doping region, and a third doping region, a top surface of the substrate exposing the first doping region and the second doping region, and a bottom of the substrate exposing the third doping region; a first gate structure and a second gate structure adjacent to each other in a first direction between the first doping region and the second doping region; and a gate separation layer in contact with the substrate between the first gate structure and the second gate structure. Each of the first gate structure and the second gate structure may include a first gate dielectric layer in contact with the substrate, a first gate conductive layer on the first gate dielectric layer, and a second gate conductive layer between the gate separation layer and the first gate conductive layer. The gate separation layer may extend in a second direction to a bottom surface of the first gate dielectric layer, and the second direction may intersect the first direction. The first gate structure and the second gate structure may overlap in a third direction with the third doping region, and the third direction may intersect the first direction and the second direction. The gate separation layer may include a first sidewall in contact with the first gate structure and a second sidewall in contact with the second gate structure. A level of top surface of the gate separation layer may be a same level as a level of a top surface of the second gate conductive layer.

According to an embodiment of inventive concepts, a semiconductor device may include a substrate including a base section, a first active pattern on the base section, and a second active pattern on the base section; a first gate structure and a second gate structure between the first active pattern and the second active pattern; and a gate separation layer between the first gate structure and the second gate structure. The substrate may include a first doping region in the first active pattern, a second doping region in the second active pattern, and a third doping region in the base section. A level of a lowermost portion of the gate separation layer may be lower than a level of a lowermost portion of the first gate structure and a level of a lowermost portion of the second gate structure.

According to an embodiment of inventive concepts, a semiconductor device may include a substrate including a first doping region, a second doping region, and a third doping region, a top surface of the substrate exposing the first doping region and the second doping region, and a bottom surface of the substrate exposing the third doping region; a first gate structure and a second gate structure between the first doping region and the second doping region; a gate separation layer between the first gate structure and the second gate structure; and a plurality of device isolation layers spaced apart from each other across the first doping region, the second doping region, the first gate structure, the second gate structure, and the gate separation layer. The first gate structure and the second gate structure may overlap the third doping region. Each of the first gate structure and the second gate structure may include a first gate dielectric layer in contact with the substrate, a first gate conductive layer on the first gate dielectric layer, a second gate dielectric layer on the first gate dielectric layer and the first gate conductive layer, and a second gate conductive layer between the gate separation layer and the first gate conductive layer. A level of a lowermost portion of the gate separation layer may be lower than a level of a bottom surface of the device isolation layer.

### BRIEF DESCRIPTION OF DRAWINGS

FIG. 1A illustrates a plan view showing a semiconductor device according to some embodiments.

FIG. 1B illustrates a cross-sectional view taken along line A-A′ of FIG. 1A.

FIG. 2 illustrates a cross-sectional view showing a semiconductor device according to some embodiments.

FIG. 3 illustrates a cross-sectional view showing a semiconductor device according to some embodiments.

FIGS. 4A to 4K illustrate cross-sectional views showing a method of fabricating a semiconductor device according to FIGS. 1A and 1B.

FIG. 5 illustrates a cross-sectional view showing a semiconductor device according to some embodiments.

FIG. 6 illustrates a cross-sectional view showing a semiconductor device according to some embodiments.

FIG. 7A illustrates a simplified block diagram showing an electronic system including a semiconductor device according to some embodiments.

FIG. 7B illustrates a simplified perspective view showing an electronic system including a semiconductor device according to some embodiments.

FIGS. 7C and 7D illustrate simplified cross-sectional views showing a semiconductor package according to some embodiments.

FIG. 8A illustrates a plan view showing a semiconductor device according to some embodiments.

FIG. 8B illustrates a cross-sectional view taken along line B-B′ of FIG. 8A.

### DETAILED DESCRIPTION OF EMBODIMENTS

It will be hereinafter discussed a semiconductor package and a method of fabricating the same according to some embodiments of inventive concepts in conjunction with the accompanying drawings.

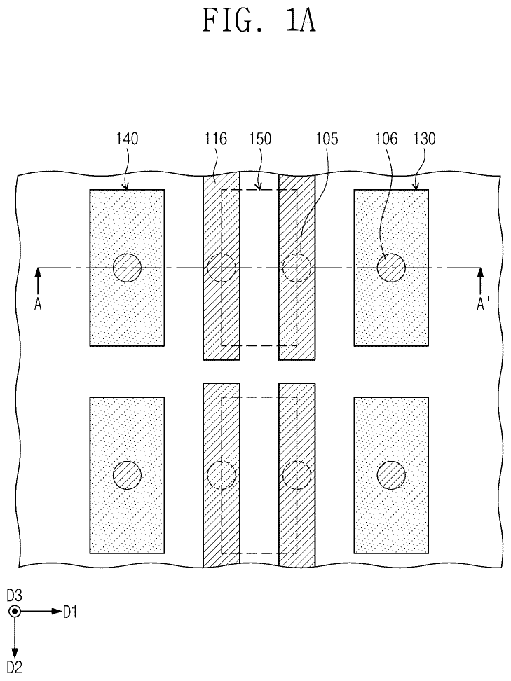

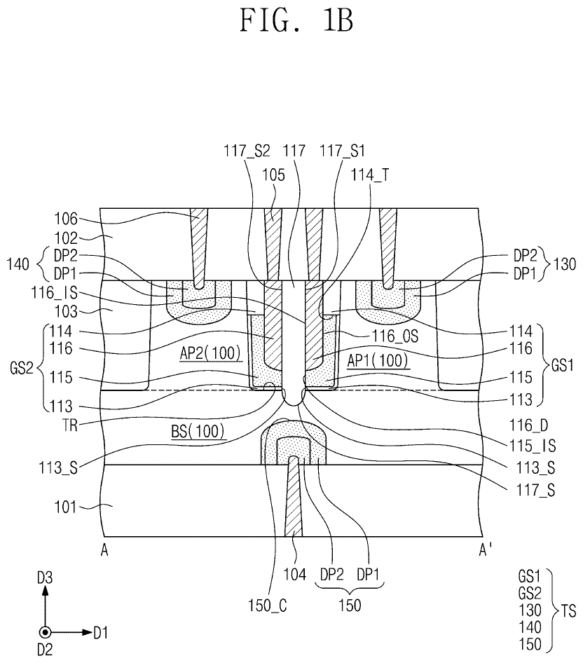

FIG. 1A illustrates a plan view showing a semiconductor device according to some embodiments. FIG. 1B illustrates a cross-sectional view taken along line A-A′ of FIG. 1A.

Referring to FIGS. 1A and 1B, a semiconductor device may include a substrate 100, a transistor TS, and a gate separation layer 117.

The substrate 100 may have a plate shape elongated along a plane defined in a first direction D1 and a second direction D2. The first direction D1 and the second direction D2 may intersect each other. For example, the first direction D1 and the second direction D2 may be horizontal directions that are orthogonal to each other. In some embodiments, the substrate 100 may be a semiconductor substrate. For example, the substrate 100 may include silicon (Si), germanium (Ge), silicon-germanium (SiGe), gallium phosphide (GaP), or gallium arsenide (GaAs). In some embodiments, the substrate 100 may be a silicon-on-insulator (SOI) substrate or a germanium-on-insulator (GOI) substrate.

The substrate 100 may include a base section BS, a first active pattern AP1, and a second active pattern AP2. The base section BS may be defined to indicate a lower portion of the substrate 100 that extends in the first direction D1 and the second direction D2. The first and second active patterns AP1 and AP2 may be defined to indicate upper portions of the substrate 100 that protrude in a third direction D3. The third direction D3 may intersect the first direction D1 and the second direction D2. For example, the third direction D3 may be a vertical direction perpendicular to the first direction D1 and the second direction D2. The first and second active patterns AP1 and AP2 may be disposed on the base section BS. The first and second active patterns AP1 and AP2 may be spaced apart from each other.

One or more device isolation layers 103 may be provided on the base section BS of the substrate 100. The device isolation layer 103 may be defined by the active patterns AP1 and AP2 of the substrate 100. The device isolation layer 103 may be disposed spaced apart in the first direction D1 from a first doping region 130, a second doping region 140, and gate structures GS1 and GS2 which will be discussed below. The first and second active patterns AP1 and AP2 may be provided between the device isolation layers 103 that are spaced apart from each other in the first direction D1. The device isolation layer 103 may be provided between the first active patterns AP1 that are spaced apart from each other in the second direction D2. The device isolation layer 103 may be provided between the second active patterns AP2 that are spaced apart from each other in the second direction D2. The device isolation layer 103 may be provided between the gate structures GS1 and GS2 that are spaced apart from each other in the second direction D2. A dielectric separation layer (not shown) may be provided between subsequently described third doping regions 150 that are spaced apart from each other in the first direction D1 or the second direction D2.

The device isolation layer 103 may include a dielectric material. For example, the device isolation layer 103 may include oxide.

The transistor TS may be provided on the substrate 100. The transistor TS may be provided between the device isolation layers 103. The transistor TS may include a first doping region 130, a second doping region 140, a third doping region 150, a first gate structure GS1, and a second gate structure GS2.

The first, second, and third doping regions 130, 140, and 150 may be formed by doping the substrate 100 with impurities. The first doping region 130 may be disposed in the first active pattern AP1 of the substrate 100. The second doping region 140 may be disposed in the second active pattern AP2 of the substrate 100. The third doping region 150 may be disposed in the base section BS of the substrate 100.

The substrate 100 may include impurities of a first conductivity type. The first, second, and third doping regions 120, 130, and 140 may include impurities of a second conductivity type different from the first conductivity type. In some embodiments, the first conductivity type may be of p-type, and the second conductivity type may be of n-type.

Each of the first, second, and third doping regions 130, 140, and 150 may include a first doping pattern DP1 and a second doping pattern DP2. The first doping pattern DP1 may surround the second doping pattern DP2. The first doping pattern DP1 and the second doping pattern DP2 may be doped with different impurities from each other. For example, the first doping pattern DP1 may be doped with phosphorus (P), and the second doping pattern DP2 may be doped with arsenic (As). In some embodiments, an impurity concentration of the first doping pattern DP1 may be less than that of the second doping pattern DP2.

The first doping region 130 may be exposed through a top surface of the substrate 100. The first doping region 130 may be disposed between the device isolation layer 103 and the first gate structure GS1. For example, a width in the first direction D1 of the first doping region 130 may be equal to or smaller than about 0.3 μm. A length in the second direction D2 of the first doping region 130 may be equal to or smaller than about 0.85 μm. The first doping region 130 may be a source region.

The second doping region 140 may be exposed through the top surface of the substrate 100. The second doping region 140 may be disposed between the device isolation layer 103 and the second gate structure GS2. For example, a width in the first direction D1 of the second doping region 140 may be equal to or smaller than about 0.3 μm. A length in the second direction D2 of the second doping region 140 may be equal to or smaller than about 0.85 μm. The second doping region 140 may be a source region.

The third doping region 150 may be exposed through a bottom surface of the substrate 100. The third doping region 150 may overlap in the third direction D3 with the first gate structure GS1, the second gate structure GS2, and the gate separation layer 117.

A width in the first direction D1 of the third doping region 150 may be smaller than a distance between the first and second doping regions 130 and 140. The width in the first direction D1 of the third doping region 150 may be smaller than a width in the first direction D1 of a trench TR of the substrate 100. For example, the width in the first direction D1 of the third doping region 150 may be equal to or smaller than about 0.3 μm. A length in the second direction D2 of the third doping region 150 may be equal to or smaller than about 0.85 μm. The third doping region 150 may be a drain region.

The first gate structure GS1 and the second gate structure GS2 may be provided in the trench TR. The first gate structure GS1 may be disposed between the first doping region 130 and the gate separation layer 117. The second gate structure GS2 may be disposed between the second doping region 140 and the gate separation layer 117. The first and second gate structures GS1 and GS2 may be spaced apart from the first, second, and third doping regions 120, 130, and 140.

Each of the first and second gate structures GS1 and GS2 may include a first gate dielectric layer 113, a second gate dielectric layer 114, a first gate conductive layer 115, and a second gate conductive layer 116. The second gate structure GS2 may be similar to the first gate structure GS1. The first gate dielectric layer 113 may be in contact with the substrate 100. The first gate conductive layer 115 may be disposed between the first gate dielectric layer 113 and the second gate conductive layer 116. The second gate conductive layer 116 may be disposed on the first gate conductive layer 115. The second gate dielectric layer 114 may be disposed on the first gate dielectric layer 113 and the first gate conductive layer 115.

The first and second gate dielectric layers 113 and 114 may include a dielectric material. For example, the first and second gate dielectric layers 113 and 114 may include oxide. The first and second gate conductive layers 115 and 116 may include a conductive material. For example, the first gate conductive layer 115 may include polysilicon. The second gate conductive layer 116 may include metal (e.g., tungsten).

The gate separation layer 117 may be provided between the first and second gate structures GS1 and GS2. The gate separation layer 117 may separate the first and second gate structures GS1 and GS2 from each other. The gate separation layer 117 may be in contact with the substrate 100. The gate separation layer 117 may extend in the second direction D2. For example, the gate separation layer 117 may extend in the second direction D2 to bottom surfaces of the second gate dielectric layers 113 of the first and second gate structures GS1 and GS2. A length in the second direction D2 of the gate separation layer 117 may be greater than a width in the first direction D1 of the gate separation layer 117. The width in the first direction D1 of the gate separation layer 117 may be smaller than a width in the first direction D1 of the device isolation layer 103. For example, the width in the first direction D1 of the gate separation layer 117 may be equal to or smaller than about 0.4 μm. The gate separation layer 117 may include a dielectric material. For example, the gate separation layer 117 may include oxide.

The gate separation layer 117 may include a first sidewall 117_S1 in contact with the first gate structure GS1 and a second sidewall 117_S2 in contact with the second gate structure GS2. The first sidewall 117_S1 of the gate separation layer 117 may be in contact with the first gate dielectric layer 113, the first gate conductive layer 115, and the second gate conductive layer 116 of the first gate structure GS1. The second sidewall 117_S2 of the gate separation layer 117 may be in contact with the first gate dielectric layer 113, the first gate conductive layer 115, and the second gate conductive layer 116 of the second gate structure GS2.

The first and second gate structures GS1 and GS2 may be disposed symmetrical to each other across the gate separation layer 117.

The first gate dielectric layer 113 may include a sidewall 113_S in contact with the gate separation layer 117. The first gate conductive layer 115 may include an inner sidewall 115_IS in contact with the gate separation layer 117.

The second gate dielectric layer 114 may include a contact surface 114_T in contact with the first gate dielectric layer 113 and the first gate conductive layer 115. In some embodiments, the second gate dielectric layer 114 may be flat at the contact surface 114_T. For example, the contact surface 114_T of the second gate dielectric layer 114 may be parallel to the top surface of the substrate 100. For example, the contact surface 114_T of the second gate dielectric layer 114 may be orthogonal to a sidewall of the second gate conductive layer 116.

The second gate conductive layer 116 may include an inner sidewall 116_IS, an outer sidewall 116_OS, and a bottom surface 116_D. The inner sidewall 116_IS of the second gate conductive layer 116 may be in contact with the gate separation layer 117. The outer sidewall 116_OS of the second gate conductive layer 116 may be in contact with the second gate dielectric layer 114 and the first gate conductive layer 115. The bottom surface 116_D of the second gate conductive layer 116 may connect to each other the inner and outer sidewalls 116_IS and 116_OS of the second gate conductive layer 116. The second gate conductive layer 116 may be curved at the bottom surface 116_D. The bottom surface 116_D of the second gate conductive layer 116 may be convex toward the first gate conductive layer 115. The bottom surface 116_D of the second gate conductive layer 116 may be located at a level that becomes higher with an increase in distance from the gate separation layer 117.

The gate separation layer 117 may include a curved surface 117_C in contact with the substrate 100. The curved surface 117_C of the gate separation layer 117 may connect to each other the first and second sidewalls 117_S1 and 117_S2 of the gate separation layer 117. The gate separation layer 117 may be curved at the curved surface 117_C.

The first sidewall 117_S1 of the gate separation layer 117 may be in contact with the sidewall 113_S of the first gate dielectric layer 113 included in the first gate structure GS1, the inner sidewall 115_IS of the first gate conductive layer 115 included in the first gate structure GS1, and the inner sidewall 116_IS of the second gate conductive layer 116 included in the first gate structure GS1. For the first gate structure GS1, the sidewall 113_S of the first gate dielectric layer 113 may be coplanar with the inner sidewall 115_IS of the first gate conductive layer 115 and the inner sidewall 116_IS of the second gate conductive layer 116.

The second sidewall 117_S2 of the gate separation layer 117 may be in contact with the sidewall 113_S of the first gate dielectric layer 113 included in the second gate structure GS2, the inner sidewall 115_IS of the first gate conductive layer 115 included in the second gate structure GS2, and the inner sidewall 116_IS of the second gate conductive layer 116 included in the second gate structure GS2. For the second gate structure GS2, the sidewall 113_S of the first gate dielectric layer 113 may be coplanar with the inner sidewall 115_IS of the first gate conductive layer 115 and the inner sidewall 116_IS of the second gate conductive layer 116.

The third doping region 150 may include a curved surface 150_C that faces the curved surface 117_C of the gate separation layer 117. The third doping region 150 may be curved at the curved surface 150_C. For example, the curved surface 150_C of the third doping region 150 may be convex toward the gate separation layer 117.

A width in the first direction D1 of the second gate conductive layer 116 may become smaller with a reduction in level of the second gate conductive layer 116.

A lowermost portion of the gate separation layer 117 may be located at a level lower than that of a lowermost portion of the first gate structure GS1 and that of a lowermost portion of the second gate structure GS2. The level of the lowermost portion of the gate separation layer 117 may be lower than those of the bottom surfaces of the first gate dielectric layers 113 of the first and second gate structures GS1 and GS2. The level of the lowermost portion of the gate separation layer 117 may be lower than that of a bottom surface of the device isolation layer 103.

The third doping region 150 may be located at a level lower than those of the first and second doping regions 130 and 140. The level of the third doping region 150 may be lower than those of the first and second gate structures GS1 and GS2. The level of the third doping region 150 may be lower than that of the gate separation layer 117.

A length in the third direction D3 of the gate separation layer 117 may be greater than a length in the third direction D3 of each of the first and second gate structures GS1 and GS2. The length in the third direction D3 of the gate separation layer 117 may be greater than a length in the third direction D3 of the device isolation layer 103.

The first and second active patterns AP1 and AP2 of the substrate 100 may have their top surfaces coplanar with those of the first and second doping regions 130 and 140, those of the first and second gate structures GS1 and GS2, and that of the gate separation layer 117. The top surface of the gate separation layer 117 may be coplanar with that of the second gate conductive layer 116. A top surface of the second gate dielectric layer 114 may be coplanar with that of the second gate conductive layer 116. A bottom surface of the substrate 100 may be coplanar with that of the third doping region 150. For example, the level of the top surface of the gate separation layer 117 may be the same as that of the top surface of the second gate conductive layer 116.

A lower dielectric layer 101 may be provided to cover the substrate 100 and the third doping region 150. The bottom surface of the substrate 100 and the bottom surface of the third doping region 150 may be in contact with the lower dielectric layer 101.

An upper dielectric layer 102 may be provided to cover the substrate 100, the device isolation layers 103, the first and second gate structures GS1 and GS2, and the first and second doping regions 130 and 140. The substrate 100, the device isolation layer 103, and the first and second doping regions 130 and 140 may have their top surfaces in contact with the upper dielectric layer 102. The second gate dielectric layer 114, the second gate conductive layer 116, and the gate separation layer 117 may have their top surfaces in contact with the upper dielectric layer 102.

The lower dielectric layer 101 and the upper dielectric layer 102 may include a dielectric material. For example, the lower dielectric layer 101 and the upper dielectric layer 102 may include oxide.

The lower dielectric layer 101 may be provided with a lower contact 104 therein. The lower contact 104 may be electrically connected to the third doping region 150. A portion of the lower contact 104 may be provided in the second doping pattern DP2 of the third doping region 150. The lower contact 104 may penetrate the lower dielectric layer 101.

The upper dielectric layer 102 may be provided therein with gate contacts 105 and upper contacts 106. The gate contacts 105 may be electrically connected to the first and second gate structures GS1 and GS2. The gate contacts 105 may be provided on the second gate conductive layers 116 of the first and second gate structures GS1 and GS2. The upper contacts 106 may be electrically connected to the first and second top contacts 130 and 140. The upper contacts 106 may have their portions that are provided in the second doping pattern DP2 of the first doping region 130 and the second doping pattern DP2 of the second doping region 140. The gate contacts 105 and the upper contacts 106 may penetrate the upper dielectric layer 102.

The lower contact 104, the gate contacts 105, and the upper contacts 106 may include a conductive material. For example, the lower contact 104, the gate contacts 105, and the upper contacts 106 may include metal.

A semiconductor device according to some embodiment may include the gate structures GS1 and GS2 that are disposed spaced apart from each other across the gate separation layer 117, and may also include the third doping region 150 that overlaps the gate structures GS1 and GS2 and are located at a level lower than those of the first and second doping regions 130 and 140. As the semiconductor device includes the gate structures GS1 and GS2 and the third doping region 150, the transistor TS may occupy a reduced area in the semiconductor device. Accordingly, the transistor TS may increase in integration and the semiconductor device may improve in electrical properties.

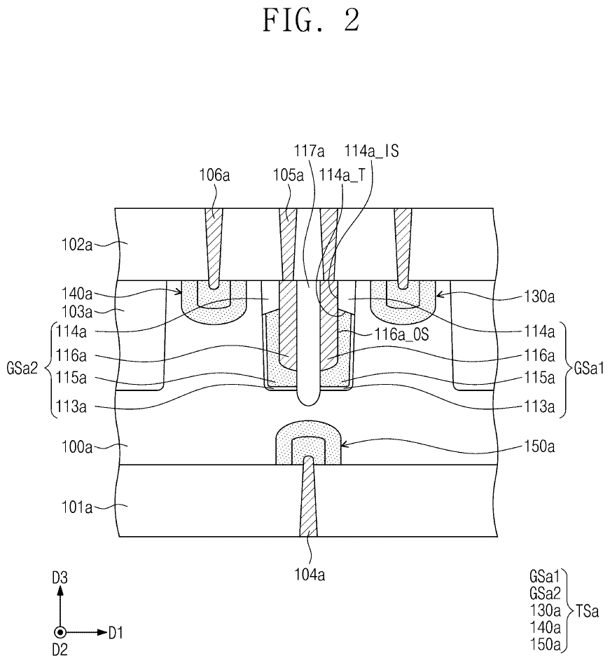

FIG. 2 illustrates a cross-sectional view showing a semiconductor device according to some embodiments.

Referring to FIG. 2, a semiconductor device may include a substrate 100a, a gate separation layer 117a, and a transistor TSa. The transistor TSa may include a first doping region 130a, a second doping region 140a, a third doping region 150a, a first gate structure GSa1, and a second gate structure GSa2.

Each of the first and second gate structures GSa1 and GSa2 may include a first gate dielectric layer 113a, a second gate dielectric layer 114a, a first gate conductive layer 115a, and a second gate conductive layer 116a. The second gate structure GSa2 may be similar to the first gate structure GSa1.

The second gate conductive layer 116a may include an outer sidewall 116a_OS in contact with the second gate dielectric layer 114a and the first gate conductive layer 115a. The second gate dielectric layer 114a may include an inner sidewall 114a_IS in contact with the outer sidewall 116a_OS of the second gate conductive layer 116a.

The second gate dielectric layer 114a may include a contact surface 114a_T in contact with the first gate dielectric layer 113a and the first gate conductive layer 115a. In some embodiments, the second gate dielectric layer 114a may be flat at the contact surface 114a_T. In some embodiments, the second gate dielectric layer 114a may be inclined at the contact surface 114a_T. For example, the contact surface 114a_T of the second gate dielectric layer 114a may be inclined with respect to the outer sidewall 116a_OS of the second gate conductive layer 116a. For example, an angle between the contact surface 114a_T and the inner sidewall 114a_IS of the second gate dielectric layer 114a may be greater than about 90 degrees and smaller than about 180 degrees.

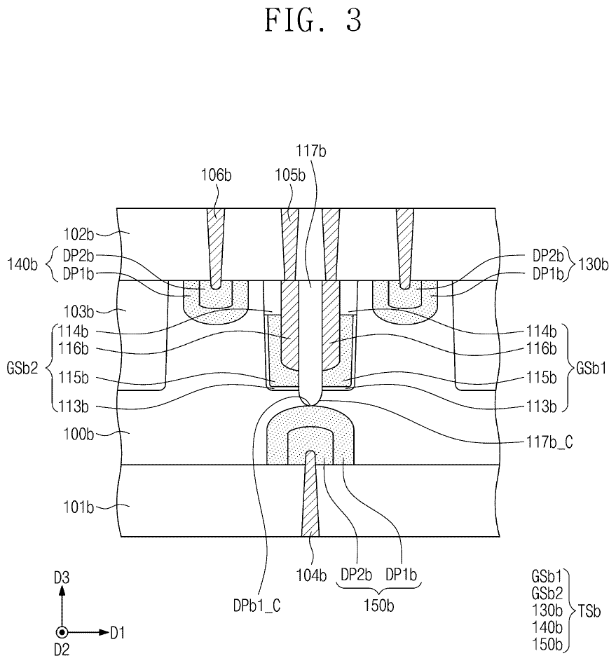

FIG. 3 illustrates a cross-sectional view showing a semiconductor device according to some embodiments.

Referring to FIG. 3, a semiconductor device may include a substrate 100b, a gate separation layer 117b, and a transistor TSb. The transistor TSb may include a first doping region 130b, a second doping region 140b, a third doping region 150b, a first gate structure GSb1, and a second gate structure GSb2.

Each of the first and second gate structures GSb1 and GSb2 may include a first gate dielectric layer 113b, a second gate dielectric layer 114b, a first gate conductive layer 115b, and a second gate conductive layer 116b. The second gate structure GSb2 may be similar to the first gate structure GSb1.

The gate separation layer 117b may include a curved surface 117b_C in contact with the substrate 100b and the third doping region 150b. The gate separation layer 117b may be curved at the curved surface 117b_C. For example, the curved surface 117b_C of the gate separation layer 117b may be convex toward the third doping region 150b.

The gate separation layer 117b may be provided between the first and second gate structures GSb1 and GSb2. The gate separation layer 117b may be in contact with the substrate 100b and the third doping region 150b. The third doping region 150b may include a first doping pattern DPb1 having a curved surface DPb1_C in contact with the gate separation layer 117b. The third doping region 150b may be curved at the curved surface DPb1_C of the first doping pattern DPb1. For example, the curved surface DPb1_C of the first doping pattern DPb1 of the third doping region 150b may be convex toward the gate separation layer 117b.

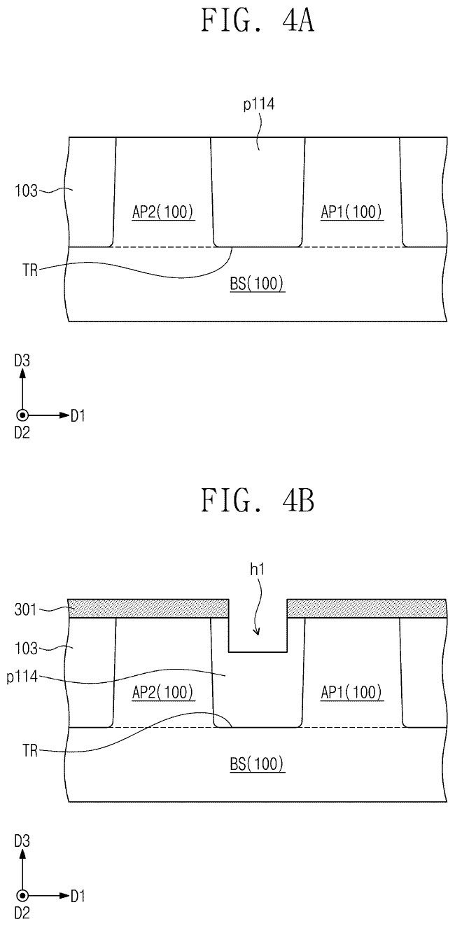

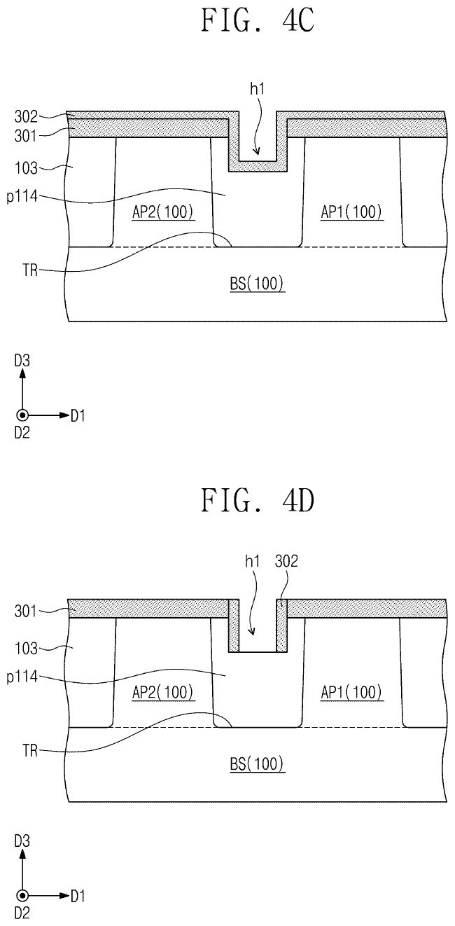

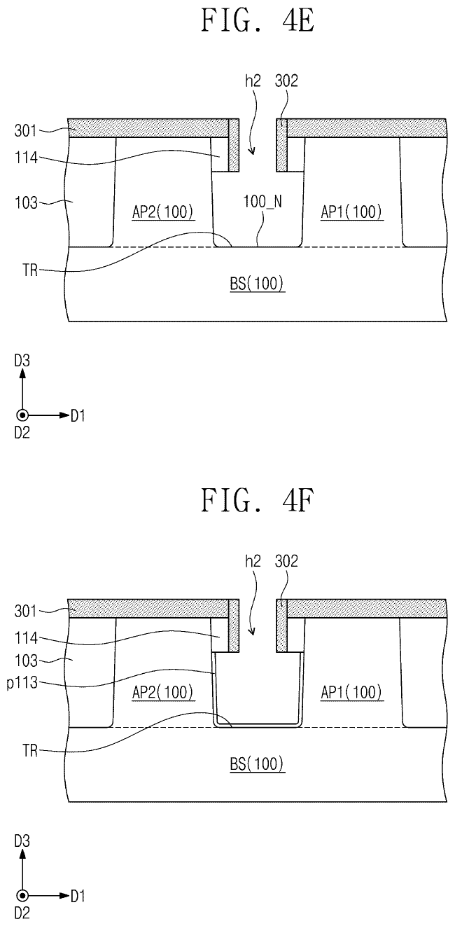

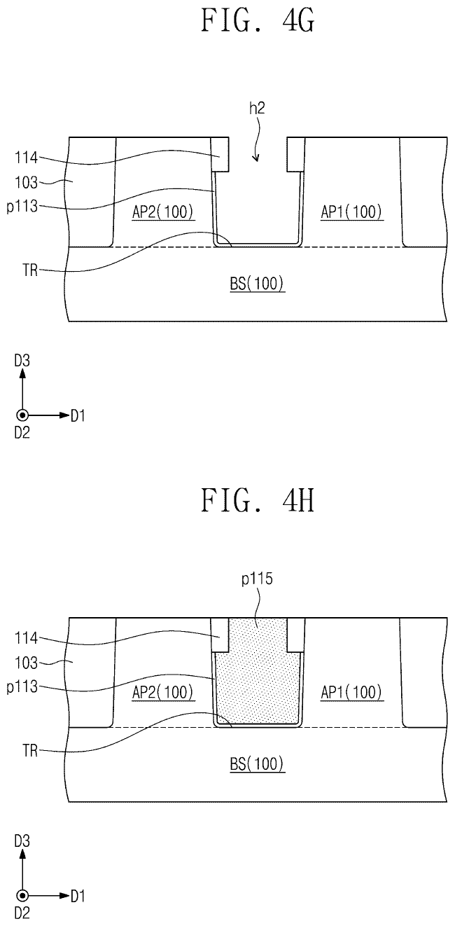

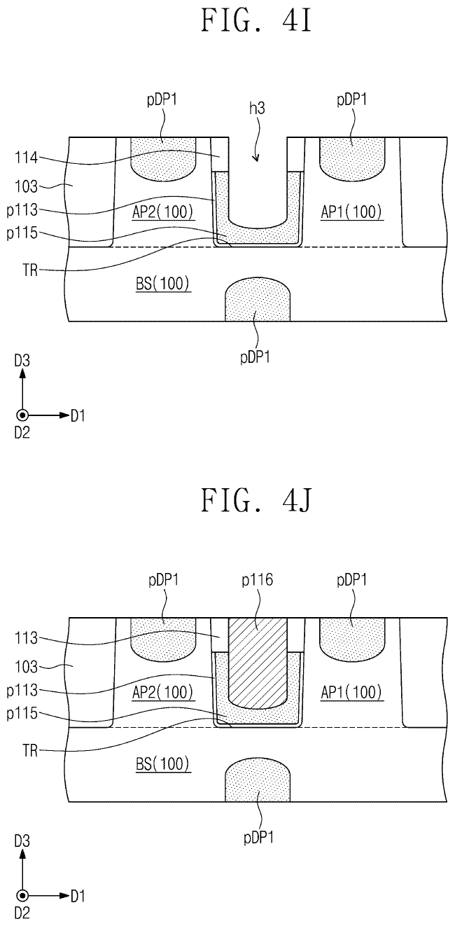

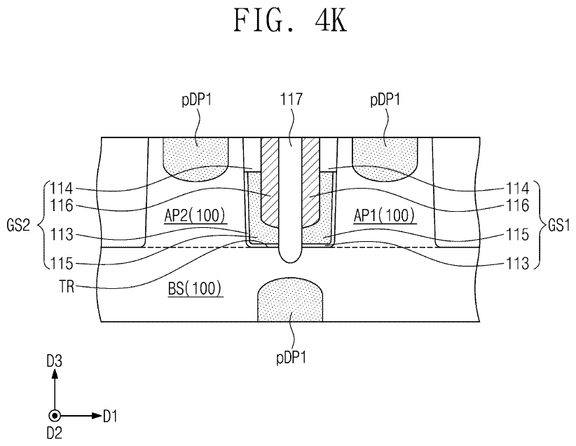

FIGS. 4A to 4K illustrate cross-sectional views showing a method of fabricating a semiconductor device according to FIGS. 1A and 1B.

Referring to FIG. 4A, a substrate 100 may be provided. One or more device isolation layers 103 may be formed in the substrate 100. A trench TR may be formed in the substrate 100. The formation of the trench TR and the device isolation layers 103 in the substrate 100 may define a base section BS, a first active pattern AP1, and a second active pattern AP2 of the substrate 100. A dielectric pattern p114 may be formed in the trench TR of the substrate 100. The dielectric pattern p114 may include a dielectric material. For example, the dielectric pattern p114 may include oxide.

Referring to FIG. 4B, a first mask pattern 301 may be formed on the first and second active patterns AP1 and AP2 and the dielectric pattern p114 of the substrate 100. The first mask pattern 301 may include a dielectric material. For example, the first mask pattern 301 may include nitride. The first mask pattern 301 may be used as an etching mask to remove a portion of the dielectric pattern p114. The dielectric pattern p114 may be partially removed to form a first opening h1. An empty space formed by the partial removal of the dielectric pattern p114 may define the first opening h1.

Referring to FIG. 4C, a second mask pattern 302 may be formed on the first mask pattern 301 and the first opening h1. The second mask pattern 302 may include a dielectric material. For example, the second mask pattern 302 may include nitride. The second mask pattern 302 may cover the dielectric pattern p114 and a sidewall of the first mask pattern 301 that are exposed through the first opening h1. In some embodiments, the second mask pattern 302 may be formed by an atomic layer deposition process.

Referring to FIG. 4D, a portion of the second mask pattern 302 may be removed. The portion of the second mask pattern 302 may be removed by an etching process. The second mask pattern 302 may be etched to expose the dielectric pattern p114 and a top surface of the first mask pattern 301.

Referring to FIG. 4E, the dielectric pattern p114 may be etched through the first opening h1. The dielectric pattern p114 may be etched to form a second gate dielectric layer 114. In some embodiments, the dielectric pattern p114 may be etched by a wet etching process. The dielectric pattern p114 may be etched to form a second opening h2. The second opening h2 may include the first opening h1 and an empty space formed by etching the dielectric pattern p114. The substrate 100 and the second gate dielectric layer 114 may be exposed through the second opening h2. A surface of the substrate 100 exposed through the second opening h2 may be defined as an exposed surface 100_N of the substrate 100.

Referring to FIG. 4F, the second opening h2 may be used to form a preliminary gate dielectric layer p113 on the exposed surface 100_N of the substrate 100. The preliminary gate dielectric layer p113 may include a dielectric material. For example, the preliminary gate dielectric layer p113 may include oxide. In some embodiments, a wet oxidation process may be employed to form the preliminary gate dielectric layer p113.

Referring to FIG. 4G, the first mask pattern 301 and the second mask pattern 302 may be removed. The first mask pattern 301 may be removed to expose the first and second active patterns AP1 and AP2 of the substrate 100. The second mask pattern 302 may be removed to expose a sidewall of the second gate dielectric layer 114. In some embodiments, an etch-back process may be used to remove the first mask pattern 301 and the second mask pattern 302.

Referring to FIG. 4H, a first conductive pattern p115 may be formed on the preliminary gate dielectric layer p113. The second opening h2 may be filled with a conductive material to form the first conductive pattern p115. For example, the first conductive pattern p115 may include polysilicon.

Referring to FIG. 4I, a preliminary doping pattern pDP1 may be formed in each of the first active pattern AP1, a preliminary doping pattern pDP1, and the base section BS. The preliminary doping patterns pDP1 in the first and second active patterns AP1 and AP2 may be formed between the device isolation layers 103 and the second gate dielectric layer 114. The preliminary doping pattern pDP1 in the base section BS may overlap the first conductive pattern p115 of the substrate 100. The preliminary doping patterns pDP1 may be formed by implanting impurities into the first active pattern AP1, the second active pattern AP2, and the base section BS. In some embodiments, the preliminary doping patterns pDP1 may be formed by an ion implantation process.

A portion of the first conductive pattern p115 may be removed. The partial removal of the first conductive pattern p115 may form a third opening h3. The third opening h3 may expose surfaces of the partially removed first conductive pattern p115 and may also expose sidewalls of the second gate dielectric layers 114. The third opening h3 may be defined by the exposed surfaces of the first conductive pattern p115 and the exposed sidewalls of the second gate dielectric layers 114. In some embodiments, a dry etching process may be adopted to partially remove the first conductive pattern p115.

Referring to FIG. 4J, the third opening h3 may be filled with a conductive material to form a second conductive pattern p116. The second conductive pattern p116 may cover the exposed surfaces of the first conductive pattern p115 and the exposed sidewalls of the second gate dielectric layer 114. The second conductive pattern p116 may include tungsten (W).

Referring to FIG. 4K, a gate separation layer 117 may be formed. The formation of the gate separation layer 117 may include removing a portion of the preliminary gate dielectric layer p113, a portion of the first conductive pattern p115, and a portion of the second conductive pattern p116.

The preliminary gate dielectric layer p113, the first conductive pattern p115, and the second conductive pattern p116 may be separated into first gate dielectric layers 113, first gate conductive layers 115, and second gate conductive layers 116, respectively, with the result that a first gate structure GS1 and a second gate structure GS2 may be defined. The preliminary gate dielectric layer p113 may be separated into the first gate dielectric layer 113 of the first gate structure GS1 and the first gate dielectric layer 113 of the second gate structure GS2. The first conductive pattern p115 may be separated into the first gate conductive layer 115 of the first gate structure GS1 and the first gate conductive layer 115 of the second gate structure GS2. The second conductive pattern p116 may be separated into the second gate conductive layer 116 of the first gate structure GS1 and the second gate conductive layer 116 of the second gate structure GS2.

Referring to FIGS. 1A and 1B, a lower dielectric layer 101 may be formed on the base section BS of the substrate 100. An upper dielectric layer 102 may be formed on the device isolation layers 103, the first and second active patterns AP1 and AP2, the first and second gate structures GS1 and GS2, and the gate separation layer 117.

A removal action may be performed to remove a portion of the lower dielectric layer 101, a portion of the upper dielectric layer 102, a portion of the preliminary doping pattern pDP1 in the first active pattern AP1, a portion of the preliminary doping pattern pDP1 in the second active pattern AP2, and a portion of the preliminary doping pattern pDP1 in the base section BS, and then second doping patterns DP2 may be formed. The second doping patterns DP2 may be formed by implanting the preliminary doping patterns pDP1 with impurities. The second doping patterns DP2 may be formed in the preliminary doping patterns pDP1, thereby forming first, second, and third doping regions 130, 140, and 150. In some embodiments, the second doping patterns DP2 may be formed by an ion implantation process.

A lower contact 104 may be formed to penetrate the lower dielectric layer 101 and to connect with the second doping pattern DP2 of the third doping region 150. An upper contact 106 may be formed to penetrate the upper dielectric layer 102 and to connect with the second doping pattern DP2 of the first doping region 130. A plurality of upper contacts 106 may be formed to penetrate the upper dielectric layer 102 and to connect with the second doping patterns DP2 of the first and second doping regions 130 and 140. A plurality of gate contacts 105 may be formed to penetrate the upper dielectric layer 102 and to connect with the second gate conductive layers 116 of the first and second gate structures GS1 and GS2.

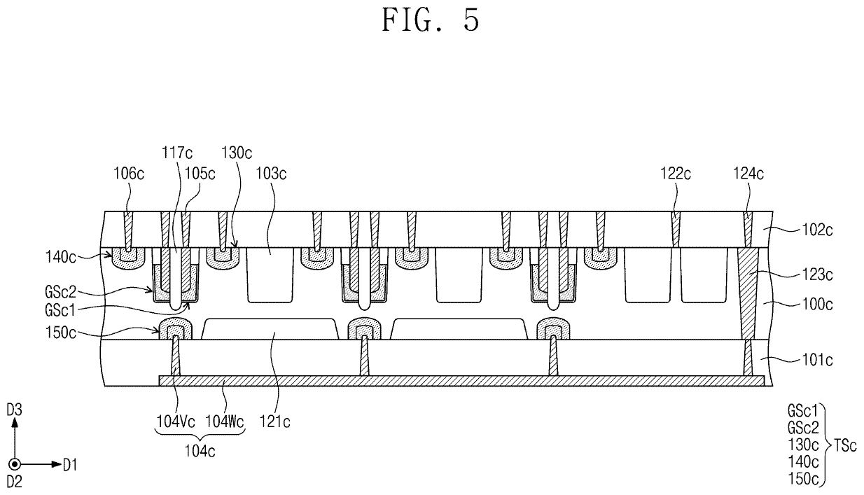

FIG. 5 illustrates a cross-sectional view showing a semiconductor device according to some embodiments.

Referring to FIG. 5, a semiconductor device may include a substrate 100c, a lower dielectric layer 101c, an upper dielectric layer 102c, transistors TSc, device isolation layers 103c, a lower contact structure 104c, upper contacts 106c, gate contacts 105c, and a gate separation layer 117c. The transistor TSc may include first doping regions 130c, a second doping region 140c, a third doping region 150c, a first gate structure GSc1, and a second gate structure GSc2.

The substrate 100c, the lower dielectric layer 101c, the upper dielectric layer 102c, the device isolation layer 103c, the upper contact 106c, the gate contact 105c, the gate separation layer 117c, the first doping region 130c, the second doping region 140c, the third doping region 150c, the first gate structure GSc1, and the second gate structure GSc2 may be layer 102, the device isolation layer 103, the upper contact 106, the gate contact 105, the gate separation layer 117, the first doping region 130, the second doping region 140, the third doping region 150, the first gate structure GS1, and the second gate structure GS2 that are discussed with reference to FIG. 1B.

The semiconductor device may further include dielectric separation layers 121c, a body contact 122c, a through via 123c, and a through contact 124c.

The dielectric separation layers 121c may be disposed in the substrate 100c. The dielectric separation layers 121c may be exposed on a bottom surface of the substrate 100c. The dielectric separation layer 121c may be disposed between the third doping regions 150c. The dielectric separation layers 121c may separate the third doping regions 150c from each other. The dielectric separation layer 121c may face the device isolation layer 103c. The dielectric separation layer 121c may overlap the device isolation layer 103c. The dielectric separation layer 121c may be spaced apart from the device isolation layer 103c. A width in the second direction D2 of the dielectric separation layer 121c may be greater than a width in the second direction D2 of the device isolation layer 103c. The dielectric separation layer 121c may include a dielectric material. For example, the dielectric separation layer 121c may include oxide.

The body contact 122c may be disposed on the substrate 100c. The body contact 122c may be disposed in the upper dielectric layer 102c. The body contact 122c may penetrate the upper dielectric layer 102c. A bottom surface of the body contact 122c may be disposed between the device isolation layers 103c. The body contact 122c may be connected to the substrate 100c and may be used to adjust threshold voltages of the transistors TSc.

The through via 123c may be disposed in the substrate 100c. The through via 123c may penetrate the substrate 100c. The through via 123c may electrically connected the lower contact structure 104c to the through contact 124c.

The through contact 124c may be disposed on the substrate 100c. The through contact 124c may be disposed in the upper dielectric layer 102c. The through contact 124c may penetrate the upper dielectric layer 102c.

The lower contact structure 104c may be disposed in the lower dielectric layer 101c. The lower contact structure 104c may include a wiring part 104Wc for horizontal connection and a plurality of via parts 104Vc for vertical connection on the wiring part 104Wc. The wiring part 104Wc of the lower contact structure 104c may be surrounded by the lower dielectric layer 101c. The via part 104Vc of the lower contact structure 104c may be surrounded by the lower dielectric layer 101c. The via part 104Vc of the lower contact structure 104c may connect the wiring part 104Wc of the lower contact structure 104c to the third doping region 150c or may connect the wiring part 104Wc of the lower contact structure 104c to the through via 123c.

The lower contact structure 104c, the body contact 122c, the through via 123c, and the through contact 124c may include a conductive material. For example, the lower contact structure 104c, the body contact 122c, the through via 123c, and the through contact 124c may include metal.

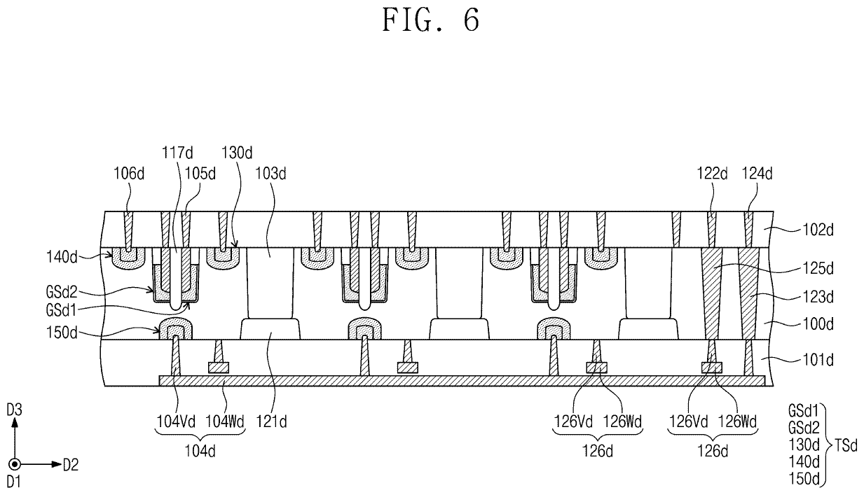

FIG. 6 illustrates a cross-sectional view showing a semiconductor device according to some embodiments.

Referring to FIG. 6, a semiconductor device may include a substrate 100d, a lower dielectric layer 101d, an upper dielectric layer 102d, transistors TSd, device isolation layers 103d, a lower contact structure 104d, upper contacts 106d, gate contacts 105d, and a gate separation layer 117d. The transistor TSd may include first doping regions 130d, a second doping region 140d, a third doping region 150d, a first gate structure GSd1, and a second gate structure GSd2.

The substrate 100d, the lower dielectric layer 101d, the upper dielectric layer 102d, the device isolation layer 103d, the upper contact 106d, the gate contact 105d, the gate separation layer 117d, the first doping region 130d, the second doping region 140d, the third doping region 150d, the first gate structure GSd1, and the second gate structure GSd2 may be layer 102, the device isolation layer 103, the upper contact 106, the gate contact 105, the gate separation layer 117, the first doping region 130, the second doping region 140, the third doping region 150, the first gate structure GS1, and the second gate structure GS2 that are discussed with reference to FIG. 1B.

The semiconductor device may further include dielectric separation layers 121d, an upper body contact 122d, a through via 123d, a through contact 124d, a body via 125d, and a lower body structure 126d.

The dielectric separation layers 121d may be disposed in the substrate 100d. The dielectric separation layers 121d may be exposed through a bottom surface of the substrate 100d. The dielectric separation layer 121d may be disposed between the third doping regions 150d. The dielectric separation layers 121d may separate the third doping regions 150d from each other. The dielectric separation layer 121d may face the device isolation layer 103d. The dielectric separation layer 121d may overlap the device isolation layer 103d. The dielectric separation layer 121d may be in contact with the device isolation layer 103d. A width in the second direction D2 of the dielectric separation layer 121d may be greater than a width in the second direction D2 of the device isolation layer 103d. The width in the second direction D2 of the dielectric separation layer 121d may be smaller than a distance between the first doping region 130d and the second doping region 140d. The dielectric separation layer 121d may include a dielectric material. For example, the dielectric separation layer 121d may include oxide.

The upper body contact 122d may be disposed on the substrate 100d. The upper body contact 122d may be disposed in the upper dielectric layer 102d. The upper body contact 122d may penetrate the upper dielectric layer 102d. The upper body contact 122d may be used to adjust threshold voltages of the transistors TSd.

The through via 123d may be disposed in the substrate 100d. The through via 123d may penetrate the substrate 100d. The through via 123d may electrically connect the lower contact structure 104d to the through contact 124d.

The through contact 124d may be disposed on the substrate 100d. The through contact 124d may be disposed in the upper dielectric layer 102d. The through contact 124d may penetrate the upper dielectric layer 102d.

The body via 125d may be disposed in the substrate 100d. The body via 125d may penetrate the substrate 100d. The body via 125d may electrically connect the upper body contact 122d to the lower body structure 126d.

The lower contact structure 104d may be disposed in the lower dielectric layer 101d. The lower contact structure 104d may include a first wiring part 104Wd for horizontal connection and a plurality of first via parts 104Vd for vertical connection on the first wiring part 104Wd. The first wiring part 104Wd of the lower contact structure 104d may be surrounded by the lower dielectric layer 101d. The first via part 104Vd of the lower contact structure 104d may be surrounded by the lower dielectric layer 101d. The first via part 104Vd of the lower contact structure 104d may connect the first wiring part 104Wd of the lower contact structure 104d to the third doping region 150d or may connect the first wiring part 104Wd of the lower contact structure 104d to the through via 123d. The lower contact structure 104d may be spaced apart from the lower body structure 126d.

The lower body structure 126d may be disposed in the lower dielectric layer 101d. The lower body structure 126d may include a second wiring part 126Wd for horizontal connection and a second via part 126Vd for vertical connection on the second wiring part 126Wd. The second wiring part 126Wd of the lower body structure 126d may be surrounded by the lower dielectric layer 101d. The second via part 126Vd of the lower body structure 126d may be surrounded by the lower dielectric layer 101d. The second via part 126Vd of the lower body structure 126d may connect the second wiring part 126Wd of the lower body structure 126d to the substrate 100d or may connect the second wiring part 126Wd of the lower body structure 126d to the body via 125d. The second wiring parts 125Wd of the lower body structures 126d may be electrically connected to each other.

The lower contact structure 104d, the upper body contact 122d, the through via 123d, the through contact 124d, the body via 125d, and the lower body structure 126d may include a conductive material. For example, the lower contact structure 104d, the upper body contact 122d, the through via 123d, the through contact 124d, the body via 125d, and the lower body structure 126d may include metal.

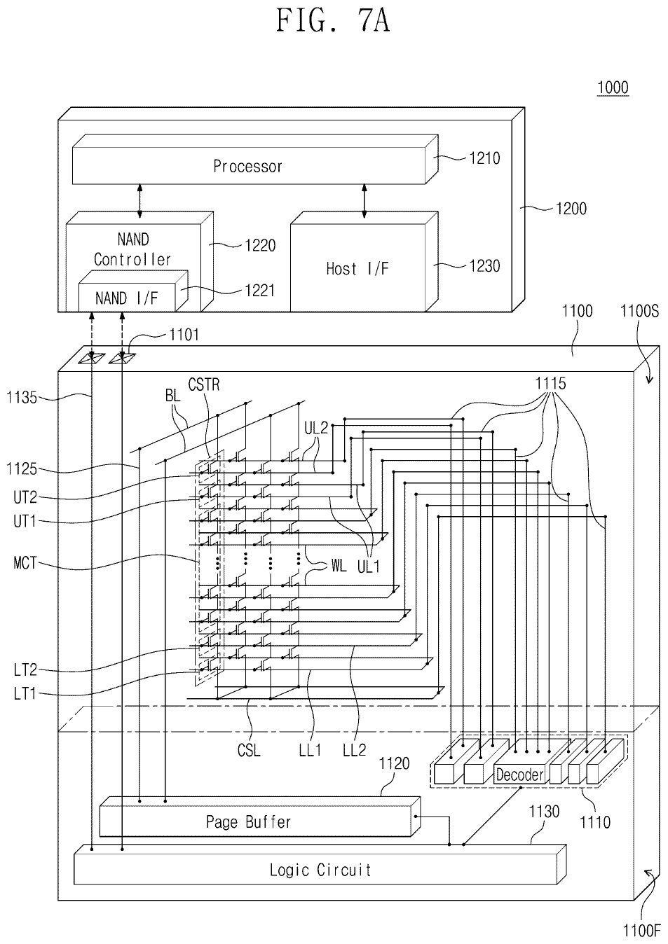

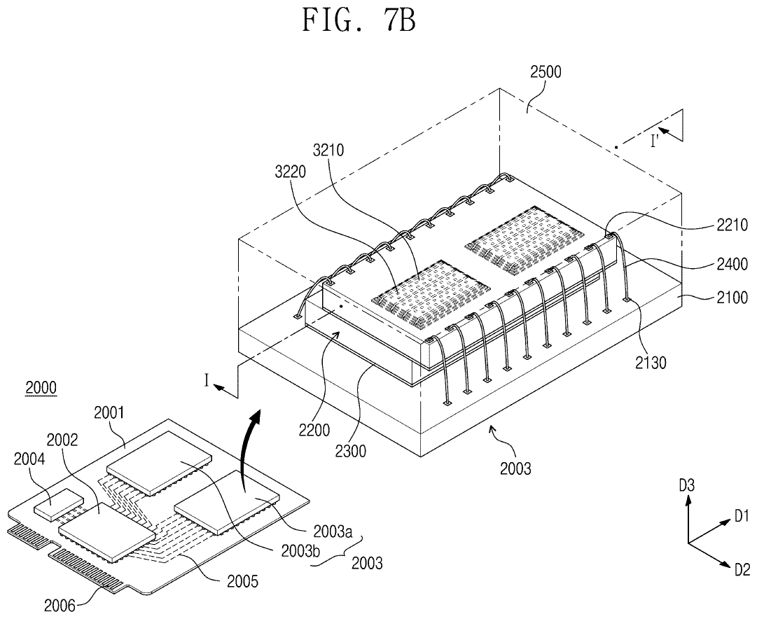

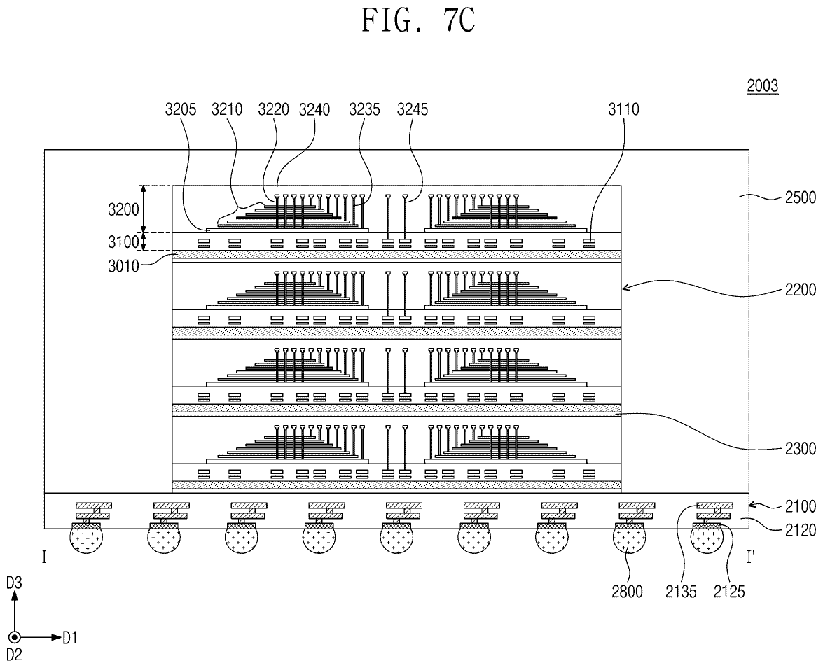

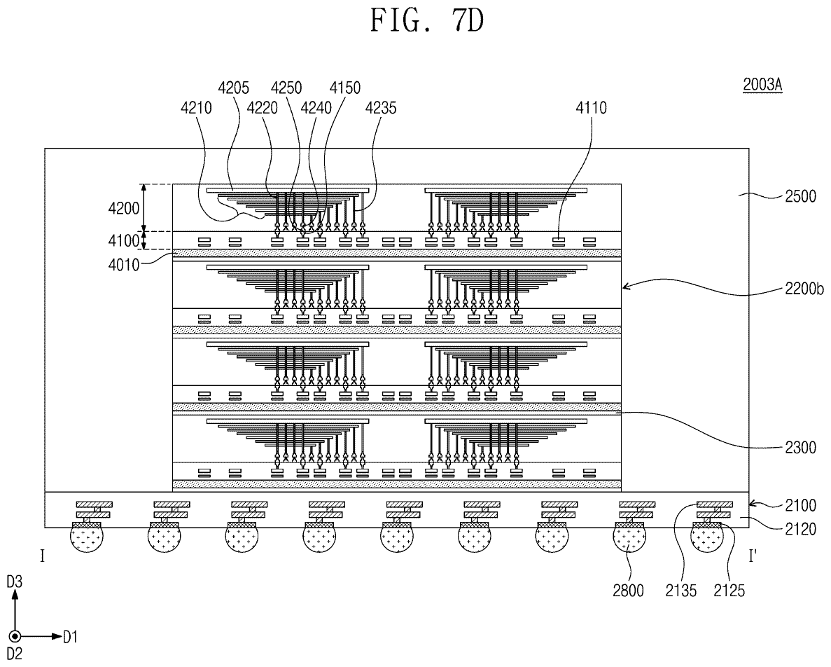

FIG. 7A illustrates a simplified block diagram showing an electronic system including a semiconductor device according to some embodiments.

Referring to FIG. 7A, an electronic system 1000 according to some embodiments may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some embodiments, the first structure 1100F may be disposed on a side of the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F to the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation on at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F to the second structure 1100S.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

FIG. 7B illustrates a simplified perspective view showing an electronic system including a semiconductor device according to some embodiments.

Referring to FIG. 7B, an electronic system 2000 according to some example embodiments may include a mainboard 2001, a controller 2002 mounted on the mainboard 2001, at least one semiconductor package 2003, and a dynamic random access memory (DRAM) 2004. The semiconductor package 2003 and the DRAM 2004 may be connected to the controller 2002 through wiring patterns 2005 formed on the mainboard 2001.

The mainboard 2001 may include a connector 2006 including a plurality of pins which will be connected to an external host. The number and arrangement of the plurality of pins on the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS). In some embodiments, the electronic system 2000 may operate with power supplied through the connector 2006 from an external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor package 2003a and 2003b may include a package substrate 2100, semiconductor chips 2200 on the package substrate 2100, adhesion layers 2300 on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be an integrated circuit board including package upper pads 2130. Each of the semiconductor chips 2200 may include one or more input/output pads 2210. The input/output pad 2210 may correspond to the input/output pad 1101 of FIG. 7A. Each of the semiconductor chips 2200 may include gate stack structures 3210 and memory channel structures 3220. Each of the semiconductor chips 2200 may include a semiconductor device which will be discussed below.

In some embodiments, the connection structures 2400 may be bonding wires that electrically connect the input/output pads 2210 to the package upper pads 2130. Therefore, in each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, in each of the first and second semiconductor packages 2003a and 2003b, the semiconductor chips 2200 may be electrically connected to each other using through-silicon vias (TSVs) instead of the connection structures 2400 or the bonding wires.

In some embodiments, the controller 2002 and the semiconductor chips 2200 may be included in one package. In some embodiments, the controller 2002 and the semiconductor chips 2200 may be mounted on a separate interposer substrate other than the mainboard 2001, and may be connected to each other through connection lines provided in the interposer substrate.

FIGS. 7C and 7D illustrate simplified cross-sectional views showing a semiconductor package according to some embodiments. FIGS. 7C and 7D each depicts an embodiment of the semiconductor package 2003 shown in FIG. 7B, conceptually showing a section taken along line I-I′ of the semiconductor package 2003 shown in FIG. 7B.

Referring to FIG. 1C, a printed circuit board may be used as the package substrate 2100 of the semiconductor package 2003. The package substrate 2100 may include a package substrate body 2120, upper pads (see 2130 of FIG. 7B) disposed on a top surface of the package substrate body 2120, lower pads 2125 disposed or exposed on a bottom surface of the package substrate body 2120, and internal lines 2135 that lie in the package substrate body 2120 and electrically connect the upper pads 2130 to the lower pads 2125. The upper pads 2130 may be electrically connected to connection structures (see 2400 of FIG. 7B). The lower pads 2125 may be connected through conductive connectors 2800 to the wiring patterns 2005 on the mainboard 2001 of the electronic system 2000, as shown in FIG. 7B.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a common source line 3205, a gate stack structure 3210 on the common source line 3205, memory channel structures 3220 that penetrate the gate stack structure 3210, bit lines 3240 electrically connected to the memory channel structures 3220, and gate contact plugs 3235 electrically connected to corresponding word lines (see WL of FIG. 7A) of the gate stack structure 3210.

Each of the semiconductor chips 2200 may include through wiring lines 3245 that are electrically connected to the peripheral wiring lines 3110 of the first structure 3100 and that extend into the second structure 3200. The through wiring line 3245 may be disposed outside the gate stack structure 3210. In some embodiments, the through wiring line 3245 may penetrate the gate stack structure 3210. Each of the semiconductor chips 2200 may further include an input/output pad (see 2210 of FIG. 7B).

Referring to FIG. 7D, in a semiconductor package 2003A, each of semiconductor chips 2200b may include a semiconductor substrate 4010, a first structure 4100 on the semiconductor substrate 4010, and a second structure 4200 provided on and wafer-bonded to the first structure 4100.

The first structure 4100 may include a peripheral circuit region including a peripheral wiring line 4110 and first bonding structures 4150. The second structure 4200 may include a common source line 4205, a gate stack structure 4210 between the common source line 4205 and the first structure 4100, memory channel structures 4220 that penetrate the gate stack structure 4210, bit lines 4240 electrically connected to the memory channel structures 4220, gate contact plugs 4235 electrically connected to corresponding word lines (see WL of FIG. 7A) of the gate stack structure 4210, and second bonding structures 4250. For example, the second bonding structures 4250 may be electrically connected to corresponding memory channel structures 4220 through the bit lines 4240 electrically connected to the memory channel structures 4220. The first bonding structures 4150 of the first structure 4100 may be bonded to the second bonding structures 4250 of the second structure 4200. The first and second bonding structures 4150 and 4250 may have their bonding portions formed of, for example, copper (Cu). Each of the semiconductor chips 2200b may further include an input/output pad (see 2210 of FIG. 7B).

The semiconductor chips 2200 of FIG. 7C or the semiconductor chips 2200b of FIG. 7D may be electrically connected to each other through the connection structures (see 2400 of FIG. 7B) shaped like bonding wires. In some embodiments, semiconductor chips in one semiconductor package, such as the semiconductor chips 2200 of FIG. 7C or the semiconductor chips 2200b of FIG. 7D, may be electrically connected to each other through connection structures including through electrodes (TSVs).

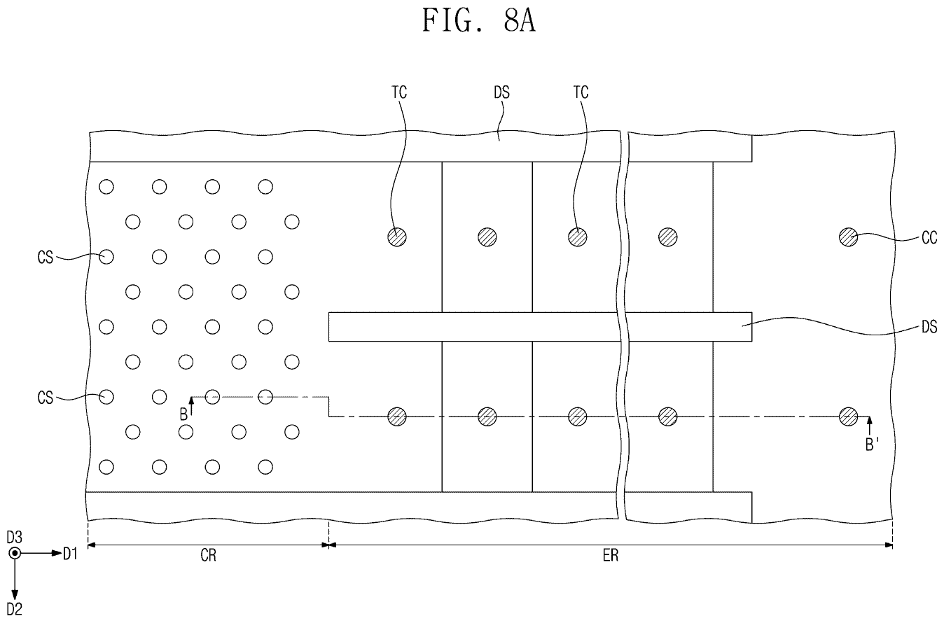

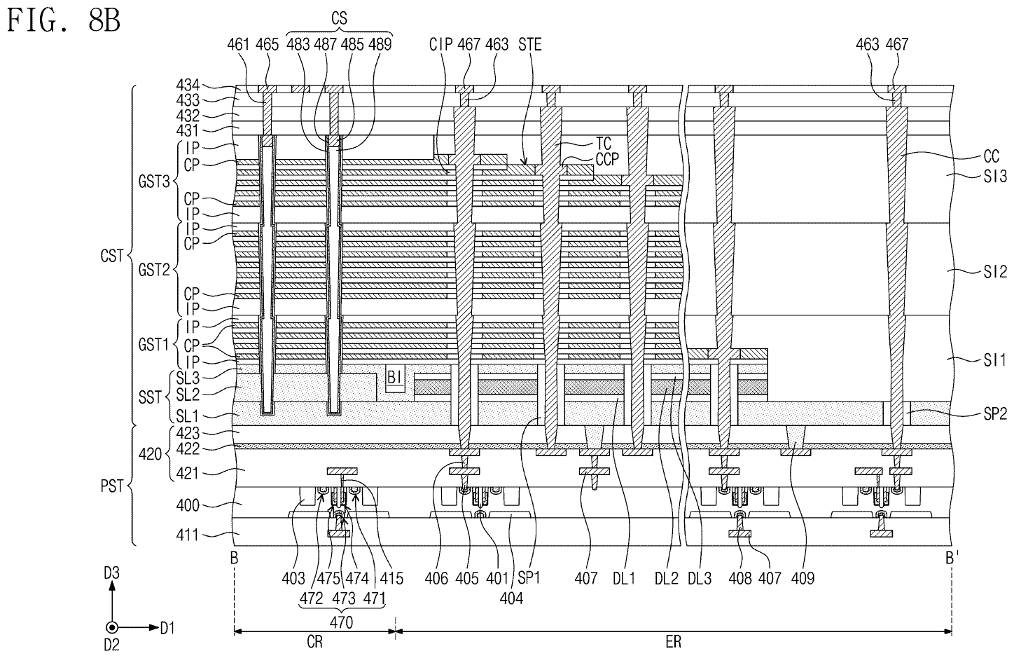

FIG. 8A illustrates a plan view showing a semiconductor device according to some embodiments. FIG. 8B illustrates a cross-sectional view taken along line B-B′ of FIG. 8A.

Referring to FIGS. 8A and 8B, a semiconductor device may include a peripheral circuit structure PST and a memory cell structure CST on the peripheral circuit structure PST.

The peripheral circuit structure PST may include a lower dielectric layer 411 and a substrate 400 on the lower dielectric layer 411. The peripheral circuit structure PST may include a dielectric structure 420 on the substrate 400. The dielectric structure 420 may include a first dielectric layer 421, a second dielectric layer 422 on the first dielectric layer 421, and a third dielectric layer 423 on the second dielectric layer 422. The first, second, and third dielectric layers 421, 422, and 423 may include a dielectric material. For example, the first and third dielectric layers 421 and 423 may include oxide, and the second dielectric layer 422 may include nitride.

In some embodiments, the first, second, and third dielectric layers 421, 422, and 423 may each be a multiple dielectric layer.

The substrate 400 may have device isolation layers 403 therein. The peripheral circuit structure PST may further include a transistor 470. The transistor 470 may be provided between the substrate 400 and the dielectric structure 420. The transistor 470 may include a first doping region 471, a second doping region 472, a third doping region 473, a first gate structure 474, and a second gate structure 475.

The peripheral circuit structure PST may further include a gate separation layer 401, dielectric separation layers 404, upper contacts 405, connection contacts 406, lower contacts 408, gate contacts 415, and peripheral conductive lines 407.

The substrate 400, the first doping region 471, the second doping region 472, the third doping region 473, the first gate structure 474, the second gate structure 475, the gate separation layer 401, the device isolation layer 403, the upper contact 405, the lower contact 408, the gate contact 415, the lower dielectric layer 411, and the first dielectric layer 421 may be respectively similar to the substrate 100, the first doping region 130, the second doping region 140, the third doping region 150, the first gate structure GS1, the second gate structure GS2, the gate separation layer 117, the device isolation layer 103, the upper contact 106, the lower contact 104, the gate contact 105, the lower dielectric layer 101, and the upper dielectric layer 102 that are discussed with reference to FIG. 1B.

The dielectric separation layer 404 may be similar to the dielectric separation layer 121c of FIG. 5. In some embodiments, the dielectric separation layer 404 may be in contact with the device isolation layer 403.

The peripheral conductive line 407 may be connected to the lower contacts 408, the upper contacts 405, the connection contacts 406, and the gate contacts 415. The connection contact 406 may be disposed between the peripheral conductive lines 407. The upper contacts 405, the connection contacts 406, the gate contacts 415, and the peripheral conductive line 407 may be provided in the first dielectric layer 421 of the dielectric structure 420. The connection contacts 406 and the peripheral conductive line 407 may include a conductive material. For example, the connection contact 406 and the peripheral conductive line 407 may include metal.

The peripheral circuit structure PST may further include a source connection contact 409. The source connection contact 409 may be connected to the peripheral conductive line 407 and a first source layer SL1 which will be discussed below. The source connection contact 409 may penetrate the second and third dielectric layers 422 and 423 of the dielectric structure 420. The source connection contact 409 may include a conductive material. For example, the source connection contact 409 may include polysilicon.

The memory cell structure CST may include a source structure SST, a first gate stack structure GST1, a second gate stack structure GST2, a third gate stack structure GST3, memory channel structures CS, a first stepwise dielectric layer SI1, a second stepwise dielectric layer SI2, a third stepwise dielectric layer SI3, a first cover dielectric layer 431, a second cover dielectric layer 432, a third cover dielectric layer 433, a fourth cover dielectric layer 434, separation structures DS, third contacts 461, fourth contacts 463, bit lines 465, conductive lines 467, through contacts TC, and connection contacts CC.

The source structure SST may include a cell region CR and an extension region ER. The cell region CR and the extension region ER may be areas divided in the first direction D1 and the second direction D2 when viewed in plan.

The source structure SST may include a first source layer SL1 on the peripheral circuit structure PST, a second source layer SL2 on the first source layer SL1, a first dummy layer DL1, a second dummy layer DL2, and a third dummy layer DL3 that are provided on the first source layer SL1, a third source layer SL3 on the second source layer SL2 and the first, second, and third dummy layers DL1, DL2, and DL3.

The first, second, and third source layers SL1, SL2, and SL3 may include a conductive material. For example, the first, second, and third source layers SL1, SL2, and SL3 may include polysilicon. The second source layer SL2 may be disposed on the cell region CR. The second source layer SL2 may be a common source line.

The first dummy layer DL1, the second dummy layer DL2, and the third dummy layer DL3 may be sequentially provided along the third direction D3 on the first source layer SL1. The first, second, and third dummy layers DL1, DL2, and DL3 may be disposed on the extension region ER. The first, second, and third dummy layers DL1, DL2, and DL3 may be located at the same level as that of the second source layer SL2. The first, second, and third dummy layers DL1, DL2, and DL3 may include a dielectric material. In some embodiments, the first and third dummy layers DL1 and DL3 may include the same dielectric material, and the second dummy layer DL2 may include a dielectric material different from that of the first and third dummy layers DL1 and DL3. For example, the second dummy layer DL2 may include nitride, and the first and third dummy layers DL1 and DL3 may include oxide.

The third source layer SL3 may cover the second source layer SL2 and the first, second, and third dummy layers DL1, DL2, and DL3. The third source layer SL3 may extend from the cell region CR toward the extension region ER.

In some embodiments, the source structure SST may further include a buried dielectric layer BI on the third source layer SL3. The buried dielectric layer BI may be provided between the cell region CR and the extension region ER. The buried dielectric layer BI may be provided between the second source layer SL2 and the first, second, and third dummy layers DL1, DL2, and DL3. The second source layer SL2 and the first, second, and third dummy layers DL1, DL2, and DL3 may be spaced apart from each other in the second direction D2 across the buried dielectric layer BI and a portion of the third source layer SL3 that surrounds the buried dielectric layer BI. The buried dielectric layer BI may include a dielectric material.

The source structure SST may further include first source dielectric patterns SP1 and second source dielectric patterns SP2. The first and second source dielectric patterns SP1 and SP2 may be disposed on the extension region ER. The first source dielectric pattern SP1 may surround the through contact TC. The second source dielectric pattern SP2 may surround the connection contact CC.

The first source dielectric pattern SP1 may penetrate the third source layer SL3, first, second, and third dummy layers DL1, DL2, and DL3, and the first source layer SL1. The first source dielectric pattern SP1 may be surrounded by the third source layer SL3, the first, second, and third dummy layers DL1, DL2, and DL3, and the first source layer SL1. The second source dielectric pattern SP2 may penetrate the first source layer SL1. The second source dielectric pattern SP2 may be surrounded by the first source layer SL1. The first and second source dielectric patterns SP1 and SP2 may include a dielectric material. For example, the first and second source dielectric patterns SP1 and SP2 may include oxide.

The first gate stack structure GST1 may be provided on the source structure SST. The second gate stack structure GST2 may be provided on the first gate stack structure GST1. The third gate stack structure GST3 may be provided on the second gate stack structure GST2. The number of the gate stack structures GST1, GST2, and GST3 may be not limited to that shown. In some embodiments, the number of the gate stack structures GST1, GST2, and GST3 may be equal to or less than 2 or equal to or greater than 4.

Each of the first, second, and third gate stack structures GST1, GST2, and GST3 may include dielectric patterns IP and conductive patterns CP that are alternately stacked along the third direction D3. A stepwise structure STE may be defined by the dielectric patterns IP and the conductive patterns CP.

The dielectric patterns IP may include a dielectric material. For example, the dielectric patterns IP may include oxide. The conductive patterns CP may include a conductive material. For example, the conductive patterns CP may include tungsten.

Each of the first, second, and third gate stack structures GST1, GST2, and GST3 may further include contact dielectric patterns CIP. The contact dielectric pattern CIP may be located at the same level as that of the conductive pattern CP. The contact dielectric pattern CIP may surround the through contact TC. The contact dielectric pattern CIP may be disposed between the through contact TC and the conductive pattern CP. The contact dielectric pattern CIP may include a dielectric material. For example, the contact dielectric pattern CIP may include oxide.

The first stepwise dielectric layer SI1 may be provided on the source structure SST. The first stepwise dielectric layer SI1 may be located at the same level as that of the first gate stack structure GST1. The second stepwise dielectric layer SI2 may be provided on the first stepwise dielectric layer SI1. The second stepwise dielectric layer SI2 may be located at the same level as that of the second gate stack structure GST2. The third stepwise dielectric layer SI3 may be provided on the second stepwise dielectric layer SI2. The third stepwise dielectric layer SI3 may be located at the same level as that of the third gate stack structure GST3. The first, second, and third stepwise dielectric layers SI1, SI2, and SI3 may include a dielectric material. For example, the first, second, and third stepwise dielectric layers SI1, SI2, and SI3 may include oxide.

The memory channel structures CS may extend in the third direction D3 to penetrate the first gate stack structure GST1, the second gate stack structure GST2, the third gate stack structure GST3, the third source layer SL3, and the second source layer SL2. Each of the memory channel structures CS may include a dielectric capping layer 189, a channel layer 187 that surrounds the dielectric capping layer 189, and a memory layer 183 that surrounds the channel layer 187.

The dielectric capping layer 189 may include a dielectric material. For example, the dielectric capping layer 189 may include oxide. The channel layer 187 may include a conductive material. For example, the channel layer 187 may include polysilicon. The channel layer 187 may be electrically connected to the second source layer SL2. The second source layer SL2 may penetrate the memory layer 183 to come into connection with the channel layer 187.

The memory layer 183 may store data. In some embodiments, the memory layer 183 may include a tunnel dielectric layer that surrounds the channel layer 187, a data storage layer that surrounds the tunnel dielectric layer, and a blocking layer that surrounds the data storage layer.

Each of the memory channel structures CS may further include a bit-line pad 185 provided on the channel layer 187. The bit-line pad 185 may include a conductive material. For example, the bit-line pad 185 may include polysilicon or metal.

The first cover dielectric layer 431 may be provided on the third gate stack structure GST3, the third stepwise dielectric layer SI3, and the memory channel structures CS. The first cover dielectric layer 431 may include a dielectric material.

The second cover dielectric layer 432 may be provided on the first cover dielectric layer 431. The second cover dielectric layer 432 may include a dielectric material.

The through contacts TC may extend in the third direction D3. The through contact TC may penetrate the second cover dielectric layer 432, the first cover dielectric layer 431, at least one selected from the first stepwise dielectric layer SI1 and the first gate stack structure GST1, at least one selected from the second stepwise dielectric layer SI2 and the second gate stack structure GST2, at least one selected from the third stepwise dielectric layer SI3 and the third gate stack structure GST3, the third source layer SL3, the third dummy layer DL3, the second dummy layer DL2, the first dummy layer DL1, the first source layer SL1, the first source dielectric pattern SP1, the third dielectric layer 423, and the second dielectric layer 422. The through contact TC may be connected to the peripheral conductive line 407. The through contact TC may include a contact connection part CCP connected to the conductive pattern CP. The through contact TC may include a conductive material.

The connection contacts CC may extend in the third direction D3. The connection contact CC may penetrate the second cover dielectric layer 432, the first cover dielectric layer 431, the first stepwise dielectric layer SI1, the second stepwise dielectric layer SI2, the third stepwise dielectric layer SI3, the first source layer SL1, the second source dielectric pattern SP2, the third dielectric layer 423, and the second dielectric layer 422. The connection contact CC may be connected to the peripheral conductive line 407.

The third cover dielectric layer 433 may be provided on the second cover dielectric layer 432, the through contacts TC, and the connection contacts CC. The fourth cover dielectric layer 434 may be provided on the third cover dielectric layer 433. The third and fourth cover dielectric layers 433 and 434 may include a dielectric material.

The separation structures DS may penetrate the first, second, and third gate stack structures GST1, GST2, and GST3. The separation structures DS may extend in the second direction D2. The separation structure DS may include a dielectric material. In some embodiments, the separation structure DS may further include a conductive material.

The third contact 461 may be connected to the memory channel structure CS. The third contact 461 may penetrate the first, second, and third cover dielectric layers 431, 432, and 433. The fourth contact 463 may be connected to the through contact TC or the connection contact CC. The fourth contact 463 may penetrate the third cover dielectric layer 433. The bit line 465 may be connected to the third contact 461. The bit line 465 may be disposed in the fourth cover dielectric layer 434. The bit line 465 may extend in the first direction D1. The conductive line 467 may be connected to the fourth contact 463. The conductive line 467 may be disposed in the fourth cover dielectric layer 434. The third contact 461, the fourth contact 463, the bit line 465, and the conductive line 467 may include a conductive material.

A semiconductor device according to some embodiments of inventive concepts may include a transistor including first to third doping regions, a first gate structure, and a second gate structure, and thus integration of the transistor may be increased to improve electrical properties.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments are described above, a person skilled in the art may understand that many modifications and variations are made without departing from the spirit and scope of inventive concepts defined in the following claims. Accordingly, the example embodiments of inventive concepts should be considered in all respects as illustrative and not restrictive, with the spirit and scope of inventive concepts being indicated by the appended claims.

What is claimed is:

1. A semiconductor device, comprising:
a substrate including a first doping region, a second doping region, and a third doping region, a top surface of the substrate exposing the first doping region and the second doping region, and a bottom of the substrate exposing the third doping region;
a first gate structure and a second gate structure adjacent to each other in a first direction between the first doping region and the second doping region; and
a gate separation layer in contact with the substrate between the first gate structure and the second gate structure,
wherein each of the first gate structure and the second gate structure include
a first gate dielectric layer in contact with the substrate,
a first gate conductive layer on the first gate dielectric layer, and
a second gate conductive layer between the gate separation layer and the first gate conductive layer,
wherein the gate separation layer extends in a second direction to a bottom surface of the first gate dielectric layer, and the second direction intersects the first direction,
wherein the first gate structure and the second gate structure overlap in a third direction with the third doping region, and the third direction intersects the first direction and the second direction,
wherein the gate separation layer includes
a first sidewall in contact with the first gate structure, and
a second sidewall in contact with the second gate structure, and
wherein a level of top surface of the gate separation layer is a same level as a level of a top surface of the second gate conductive layer.

2. The semiconductor device of claim 1, wherein
a width in the first direction of the third doping region is smaller than a distance between the first doping region and the second doping region.

3. The semiconductor device of claim 1, wherein
a curved surface of the third doping region faces the gate separation layer, and
the curved surface of the third doping region is convex toward the gate separation layer.

4. The semiconductor device of claim 1, wherein
the first gate structure and the second gate structure each further include a second gate dielectric layer,
the second gate dielectric layer of the first gate structure is on the first gate dielectric layer of the first gate structure and the first gate conductive layer of the first gate structure,
the second gate dielectric layer of the second gate structure is on the first gate dielectric layer of the second gate structure and the first gate conductive layer of the second gate structure, and
the first sidewall of the gate separation layer is in contact with a sidewall of the first gate dielectric layer of the first gate structure.

5. The semiconductor device of claim 4, wherein
an inner sidewall of the first gate conductive layer of the first gate structure is in contact with the gate separation layer, and
the inner sidewall of the first gate conductive layer of the first gate structure is coplanar with the sidewall of the first gate dielectric layer of the first gate structure.

6. The semiconductor device of claim 4, wherein
a contact surface of the second gate dielectric layer of the first gate structure is in contact with the first gate dielectric layer of the first gate structure and with the first gate conductive layer of the first gate structure.

7. The semiconductor device of claim 6, wherein the contact surface of the second gate dielectric layer of the first gate structure is parallel to the top surface of the substrate.

8. The semiconductor device of claim 6, wherein
the contact surface of the second gate dielectric layer of the first gate structure is inclined with respect to the top surface of the substrate.

9. The semiconductor device of claim 4, wherein
a width in the first direction of the second gate conductive layer of the first gate structure becomes smaller with a reduction in level of the second gate conductive layer of the first gate structure.

10. The semiconductor device of claim 4, wherein
an inner sidewall of the second gate conductive layer of the first gate structure is in contact with the gate separation layer,
an outer sidewall of the second gate conductive layer of the first gate structure is in contact with the second gate dielectric layer of the first gate structure and in contact with the first gate conductive layer of the first gate structure, and
a bottom surface of the second gate conductive layer of the first gate structure connects the inner sidewall of the second gate conductive layer to the outer sidewall of the second gate conductive layer.

11. The semiconductor device of claim 10, wherein
in at least one of the first gate structure and the second gate structure, the bottom surface of the second gate conductive layer is curved.

12. The semiconductor device of claim 10, wherein
in at least one of the first gate structure and the second gate structure, a level of the bottom surface of the second gate conductive layer becomes higher as a distance of the bottom surface of the second gate conductive layer from the gate separation layer increases.

13. A semiconductor device, comprising:
a substrate including a base section, a first active pattern on the base section, and a second active pattern on the base section;
a first gate structure and a second gate structure between the first active pattern and the second active pattern; and
a gate separation layer between the first gate structure and the second gate structure,
wherein the substrate includes a first doping region in the first active pattern, a second doping region in the second active pattern, and a third doping region in the base section, and
wherein a level of a lowermost portion of the gate separation layer is lower than a level of a lowermost portion of the first gate structure and a level of a lowermost portion of the second gate structure.

14. The semiconductor device of claim 13, wherein the first gate structure and the second gate structure are spaced apart from the first doping region, the second doping region, and the third doping region.

15. The semiconductor device of claim 13, further comprising:
a device isolation layer spaced apart in a first direction from the first doping region and the first gate structure, wherein
a width in the first direction of the gate separation layer is smaller than a width in the first direction of the device isolation layer.

16. The semiconductor device of claim 13, wherein the gate separation layer is in contact with the third doping region.

17. The semiconductor device of claim 13, wherein a top surface of the first active pattern, a top surface of the second active pattern, a top surface of the first gate structure, and a top surface of the gate separation layer are coplanar with each other.

18. The semiconductor device of claim 13, wherein
the first active pattern, the second active pattern and the base section of the substrate include impurities of a first conductivity type, and
the first doping region, the second doping region, and the third doping region include impurities of a second conductivity type.

19. A semiconductor device, comprising:
a substrate including a first doping region, a second doping region, and a third doping region, a top surface of the substrate exposing the first doping region and the second doping region, and a bottom surface of the substrate exposing the third doping region;
a first gate structure and a second gate structure between the first doping region and the second doping region;
a gate separation layer between the first gate structure and the second gate structure; and
a plurality of device isolation layers spaced apart from each other across the first doping region, the second doping region, the first gate structure, the second gate structure, and the gate separation layer,
wherein the first gate structure and the second gate structure overlap the third doping region,
wherein each of the first gate structure and the second gate structure include
a first gate dielectric layer in contact with the substrate,
a first gate conductive layer on the first gate dielectric layer,
a second gate dielectric layer on the first gate dielectric layer and the first gate conductive layer, and
a second gate conductive layer between the gate separation layer and the first gate conductive layer,
wherein a level of a lowermost portion of the gate separation layer is lower than a level of a bottom surface of the device isolation layer.

20. The semiconductor device of claim 19, further comprising:
a plurality of upper contacts correspondingly connected to the first doping region and the second doping region;
a plurality of gate contacts correspondingly connected to the second gate conductive layer of the first gate structure and the second gate conductive layer of the second gate structure; and
a lower contact connected to the third doping region.
